(19) United States
(12) Patent Application Publication
(10) Pub. No.: US 2015/0061650 A1
(43) Pub. Date: Mar. 5, 2015

(54) METHOD AND ARRANGEMENT AND SENSOR FOR DETERMING THE POSTION OF A COMPONENT

(71) Applicant: ASG LUFTFAHRTTECHNIK UND SENSORIK GMBH, Weinheim (DE)

(72) Inventor: Reiner Strietzel, Heidelberg (DE)

(21) Appl. No.: 14/390,261

(22) PCT Filed: Mar. 28, 2013
(86) PCT No.: PCT/EP2013/056748

§ 371 Date: Nov. 7, 2014

(30) Foreign Application Priority Data
Apr. 2, 2012 (DE) 10 2012 102 855.9

(51) Int. Cl. G01D 5/20; G01R 1/12

(52) U.S. Cl. CPC G01D 5/20; G01R 1/12
USPC 324/207.15

(57) ABSTRACT

The invention relates to a method and an arrangement for determining a position of a first component (14) such as a piston rod in relation to a second component (12) such as a hydraulic, electrical or pneumatic cylinder, wherein at least one first magnetically scannable structure (34) such as a measurement strip formed on a surface (18) of said first component (14) is detected by means of at least one first magnetic flux sensor (22) connected to the second component (12) during a relative movement between the first component (14) and the magnetic flux sensor (22). To improve the accuracy of the position determination, the method is executed according to the invention as a differential measuring method, wherein a differential transformer is used as the magnetic flux sensor (22), and wherein the position of the first component (14) in relation to the second component (12) is determined absolutely, wherein a second magnetically scannable structure (28) arranged on the surface (18) of the first component (14) is detected by means of at least one second magnetic flux sensor (32) connected to the second component (12), and wherein the absolute position of the first component (14) is determined from the signal sequence of the first magnetic flux sensor (22) and the continuous output signal of the second magnetic flux sensor (32).

The invention relates to a method according to the preamble of claim 1, an arrangement for determining position according to the preamble of claim 6, and a sensor according to the preamble of claim 16.

U.S. Pat. No. 7,652,469 B2 describes an inductive position sensor having a spatially periodic scale with a series of conducting or permeable features at distance T, and a reading head with drive windings and sense windings, arranged facing the scale with a spatial period 2T along the scale. The windings are each divided into two identical winding elements having the same relative arrangement within two identical winding element patterns having a center-to-center distance along the scale of NT+T/2, wherein the windings are connected to one another in such a way that the winding element polarities in each winding are either opposed for drive windings or the same for sense windings.

U.S. Pat. No. 7,667,455 B2 relates to an annular magnetic encoder comprising a plurality of south magnetic poles and north magnetic poles, arranged alternately in an arrangement pattern. This case likewise utilizes a differential measuring method, in which a differential transformer is used as the magnetic flux sensor.

U.S. Pat. No. 8,004,277 B2 relates to an angular position sensor for determining angular position, comprising a shaft having a threaded portion and a structure for engaging an external arrangement. The shaft comprises a first permanent magnet. A nut is threaded onto the threaded portion and is formed from a first magnetic permeable material or comprises a second permanent magnet. At least one constraint is coupled to the nut for preventing rotational movement of the screw while allowing linear motion of the screw while the shaft rotates. A first magnetic sensor is positioned along a length of the threaded portion, for the purpose of measuring a linear position of the nut. A second magnetic sensor is provided for measuring an angular position of the shaft. Signal processing circuitry is coupled to the first magnetic sensor and the second magnetic sensor in order to determine parameters relating to an angular position of the rotating part.

U.S. Pat. No. 6,011,389 A relates to a current inducing position transducer having a low-power electronic circuit. The described sensor arrangement is embodied as a differential transformer. At least one transformer winding could also be designed as a primary winding and another winding as a secondary winding.

From DE 102 48 142 B3 a method for producing a magnetically scannable coding in a metallic component and a metallic component having a corresponding magnetically scannable coding is known. The coding comprises code elements which are produced in that structural changes that persist in the component are generated as having a magnetic conductivity different from that of the untreated material of the component. Said document also describes how the code elements are read out. In this process, the component is moved relative to the magnetic field sensor, which detects the different magnetic properties and/or magnetic flux changes between the code elements and the material encompassing said elements. In this manner, the code elements can be detected for the purpose of identifying or determining the position of the component.

The known sensor is a magnetic field sensor having a single coil, which can result in inaccuracies in practical use.

Proceeding from the above, the object of the present invention is to develop a method and an arrangement of the type described in the introductory part such that the accuracy of position determination is improved.

The object is attained according to the invention, i.e., in that the method is executed as a differential measurement method in which a differential transformer having a primary winding and two secondary windings is used as the magnetic flux sensor. The primary winding is excited with AC voltage, so that a differential signal can be picked up as an output signal at the secondary windings. The magnetically scannable structures, such as measurement strips, which are introduced into the metallic surface of the component by structural changes, such as selective hardening, can be detected by various physical methods. In particular, changes in magnetic permeability, such as eddy losses or other processes, can be used to detect selectively introduced structural changes. A differential measuring method according to the invention has proven particularly suitable for this purpose, because it enables continuous measurement and allows interference effects to be eliminated.

To achieve particularly high accuracy, magnetically scannable measurement strips, preferably extending as components of a scale, arranged equidistant along the longitudinal axis of the first component and transversely to the longitudinal axis, are used as the first magnetically scannable structure, and a continuous sine signal or cosine signal is generated during a relative movement of the measurement strip.

The primary winding of the differential transformer is excited with AC voltage and the secondary windings are preferably interconnected in phase. As a result, all in-phase signals are eliminated. Therefore, only differential signals occur as output signals. When a sensor head of this configuration moves along a scale of equidistant measurement strips, the output signal is continuously sinusoidal and highly stable, allowing very high resolution to be achieved.

According to a preferred procedure, it is provided that the position of the first component in relation to the second component is determined absolutely, wherein a second magnetically scannable structure arranged on the surface of the first component is detected by means of at least one second magnetic flux sensor connected to the second component, and that two magnetically scannable measurement strips, extending along the longitudinal axis in a V-shape, symmetrically to the longitudinal axis of the component, are used as the second magnetically scannable structure.

If a blank space and a measurement strip of the above-mentioned scale are viewed as sectors, for example, a so-called sector pointer is proposed for measuring absolute value. Said sector pointer is implemented according to the invention by the second measurement strip arrangement in the form of a linear measurement system, which requires substantially lower resolution as compared with the first scale.

The second measurement strip arrangement can be scanned using the same differential transformer as the magnetic flux sensor, specifically for long distances, but with lower resolution. The measurement strips are preferably embodied as selectively hardened strips on the metallic surface of the component, extending at an angle in the longitudinal direction.

A further preferred procedure is characterized in that, when the component moves linearly, the measurement strips are moved transversely to a sensor surface of the second magnetic flux sensor along the sensor surface, so that a continuous output signal that is dependent on the position of the first component is generated in the second magnetic flux sensor. Thus the absolute position of the first component can be determined from the signal sequence of the first magnetic flux sensor and the continuous output signal of the second magnetic flux sensor. To further improve resolution, it is proposed that at least two of the first magnetic flux sensors are arranged spatially offset from one another such that, when the component moves linearly, a first magnetic flux sensor at the front generates a sine signal and a first magnetic flux sensor at the rear generates a cosine signal.

The invention further relates to an arrangement for determining a position of a first component, such as a piston rod, in relation to a second component, such as a hydraulic or pneumatic cylinder, said arrangement comprising at least one first magnetic flux sensor connected to the second component for detecting a first magnetically scannable structure, such as measurement strips, formed on a surface of the first component, during a relative movement between the first component and the magnetic flux sensor. This arrangement is characterized in that the at least one first magnetic flux sensor is embodied as a differential transformer.

The differential transformer comprises a primary winding and two secondary windings, wherein the primary winding is connected to an alternating current generator, and wherein the two secondary windings are preferably interconnected in phase and connected to an evaluation unit.

The system for measuring the absolute position of the component preferably has at least one second magnetic flux sensor, which detects a second magnetically scannable measurement strip structure extending along a longitudinal axis of the component, wherein the second magnetically scannable measurement strip arrangement comprises a V-shaped measurement strip extending along the longitudinal axis, which traverses a sensor surface of the second magnetic flux sensor during linear movement of the component.

A preferred embodiment of the arrangement is characterized in that primary and secondary windings of the differential transformer are embodied as inductors arranged within a single plane, and positioned adjacent to one another on a substrate so as to form a sensor surface, wherein the magnetic axes thereof extend parallel to one another. In said embodiment, the inductor is designed as an SMD (surface mounted device) inductor or miniature inductor.

According to a further preferred embodiment, it is provided that the arrangement is a hydraulic, electric, pneumatic or other drive, wherein the first component is embodied as a piston rod and wherein the second component is embodied as a hydraulic, electric, pneumatic or other cylinder within which the piston rod is displaceable longitudinally.

In this embodiment, the magnetic flux sensor can be is arranged on an inner edge of a sensor holder which is arranged on the hydraulic or pneumatic cylinder, bordering the surface of the piston rod for the purpose of detecting the arrangement of the measurement strips. The sensor holder is preferably embodied as a sensor ring that is connected to the end face of the cylinder.

For determining absolute position, it is provided that the first and second magnetically scannable measurement strip arrangements are formed on diametrically opposite surfaces of the piston rod, and that the first and second magnetic flux sensors are arranged at diametrically opposite positions on the sensor holder that encompasses the end face, wherein each of the first and second magnetic flux sensors is arranged in a recess in an inner surface of the sensor holder.

Even higher resolution is achieved by providing a plurality of first or second magnetic flux sensors, which are offset spatially such that, when the first component moves linearly, a sine signal and a cosine signal are generated as output signals.

The invention further relates to a sensor for detecting a magnetically scannable measurement strip structure, formed on a metallic surface of a component, during a relative movement between the sensor and the component, wherein the sensor comprises at least one transformer winding. The sensor is preferably embodied as a differential transformer. Said transformer comprises at least one transformer winding as a primary winding and two additional windings as secondary windings, wherein the primary and secondary windings can be embodied as SMD inductors or miniature inductors, and are arranged magnetically coupled and flat on a substrate.

Each of the SMD inductors preferably has a magnetic axis, and the inductors are arranged adjacent to one another such that the magnetic axes extend parallel to one another.

Additional details, advantages and features of the invention are described not only in the claims, in the features specified therein—alone and/or in combination,—but also in the following description of one of the preferred embodiment examples depicted in the set of drawings.

The drawings show:

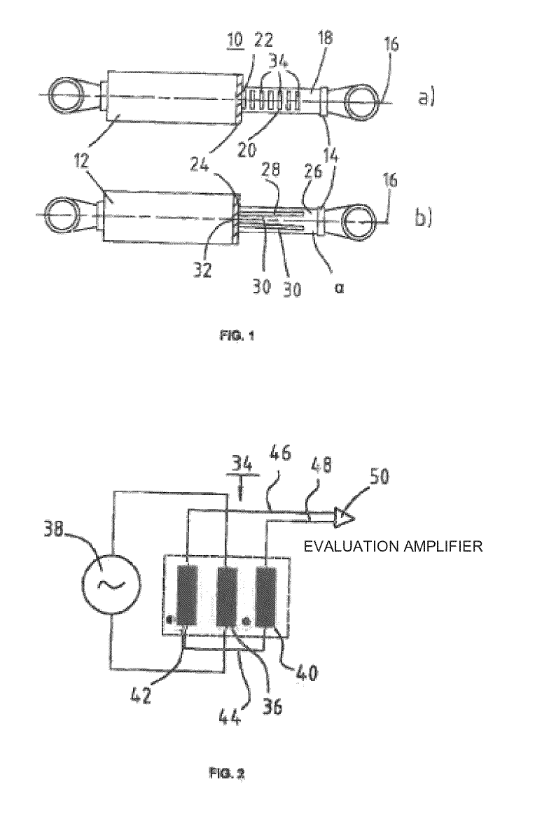

FIG. 1a a plan view of a hydraulic drive with hydraulic cylinder and piston rod,

FIG. 1b a bottom view of the hydraulic drive with hydraulic cylinder and piston rod,

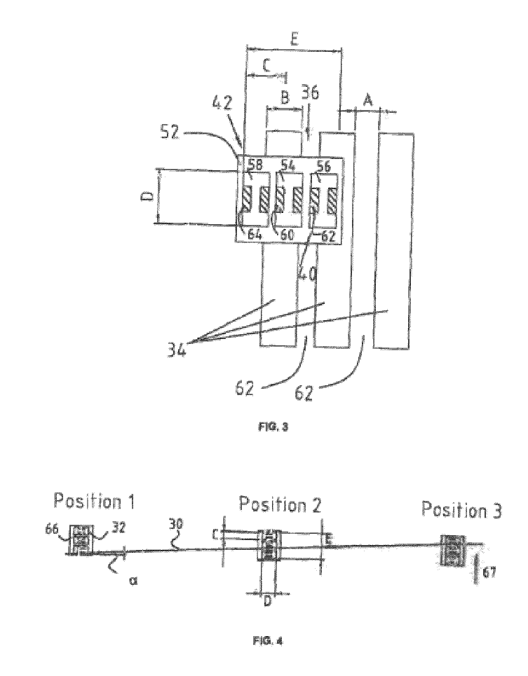

FIG. 2 a wiring diagram of a magnetic flux sensor configured as a differential transformer,

FIG. 3 a schematic illustration of a sensor head of the magnetic flux sensor in relation to a magnetically scannable measurement strip of the piston rod,

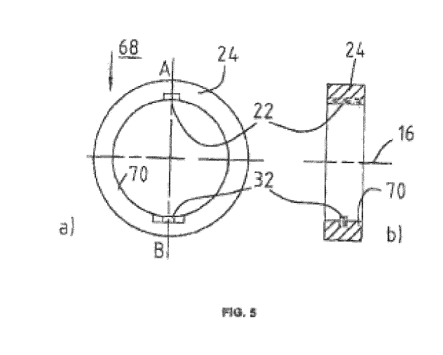

FIG. 4 a schematic illustration of a measurement strip that extends in the longitudinal direction of the piston rod and a sensor head in different positions,

FIG. 5a a front view of a sensor ring for holding the magnetic flux sensors and

FIG. 5b a sectional illustration of the sensor ring.

FIG. 1a shows a plan view of a hydraulic drive 10, comprising a hydraulic cylinder 12 in which a piston rod 14 is arranged so as to be movable along a longitudinal axis 16. A first magnetically scannable structure 20 in the form of equidistant measurement strips 34 is positioned on a metallic surface 18 of the piston rod 14. These strips are detected by means of a first magnetic flux sensor 22, which is arranged stationarily on the hydraulic cylinder 12, preferably in an end-face sensor ring 24.

For determining absolute position, a second magnetically scannable structure 28 comprising first and second measurement strips 30 extending preferably in a V-shape along the longitudinal axis 16 is provided on a bottom side 26 of the cylindrical piston rod 14. The measurement strips 30 extend at an angle α relative to the longitudinal axis 16, with a measuring within a range of 0.2°≦α≦20°, preferably with α=1° to 2°.

The first magnetically scannable structure 34, which comprises individual measurement strips 20 arranged equidistant from one another, is produced by thermal structural change, e.g. by the selective hardening of the surface 18 of the piston rod 14, which is made of steel. The structural change can be generated by selective laser hardening or similar methods, such as electron beam hardening or selective soft annealing. Another option consists in introducing microgrooves into the surface of the piston rod 14 or by other structure modifying measures, and filling said microgrooves with a material, the permeability and/or magnetic property of which is different from that of the material of the surface. Once the measurement strip 34, 30 has been introduced into the piston material, the surface 18, 26 of the piston rod 14 is ground and hard-faced, e.g. with chromium or nickel-chromium.

The measurement strips 30 of the second structure 28 are detected by means of a second magnetic flux sensor 32.

According to the invention, the magnetically scannable structures 34, 30 are detected by means of a differential measuring method. This has the advantage of increasing accuracy and eliminating interference effects.

The magnetic flux sensor 22 or 32 for implementing the method is represented purely schematically in FIG. 2. According to the invention, the magnetic flux sensor 22, 32 is embodied as a differential transformer 34. The differential transformer 34 comprises a primary winding 36 which is connected to an AC voltage generator 38, and a sine signal is preferably excited with AC voltage.

The differential transformer 34 further comprises outer secondary windings 40, 42, which are magnetically coupled to the primary winding 26, and which are interconnected in phase via a connection 44. Outputs 46, 48 of the respective secondary windings 40, 42 are connected to an evaluation circuit 50 such as an evaluation amplifier.

FIG. 3 shows a schematic plan view of a sensor head 52 of differential transformer 36, 40, 42 in relation to measurement strips 34 according to FIG. 1a. Measurement strips 34 are arranged at equidistant spacing A in the longitudinal direction to form a scale, wherein spacing A is preferably within a range of 1 mm≦A≦20 mm, preferably with A=5 mm. The width B of measurement strips 34 is within a range of 0.5 mm≦B≦10 mm, preferably with B=5 mm.

In the embodiment example represented here, primary winding 36 and secondary windings 40, 42 are embodied as SMD (surface mounted device) inductors. Each of SMD inductors 36, 40, 42 comprises a magnetic core 54, 56, 58, with each core bearing a coil 60, 62, 64. Said coils are arranged on a support within a single plane.

Magnetic cores 54, 56, 58 are arranged with their magnetic axes parallel to one another and close one behind the other in the direction of movement of the piston rod 14, wherein transformer cores 54, 56, 58 are aligned parallel to measurement strips 34.

It is further provided that the width C of SMD inductors 36, 40, 42 is within a range of 0.5 mm≦C≦10 mm. Moreover, the length D of the SMD inductors is within a range of 1 mm≦D≦20 mm.

As described above, differential transformer 34 comprises primary winding 36 and secondary windings 40, 42, wherein the latter are connected in phase opposition or in phase, depending on the evaluation method that is applied (differential or non-differential). The steady components of the voltages are thereby eliminated at connections 46, 48. The resulting voltage is then precisely zero when both windings and the entire structure are symmetrically structured. If this symmetry is altered, e.g. by movements of magnetic flux sensor 22, 32 relative to measurement strips 34, 30, an output voltage will result, the amplitude of which indicates the degree of asymmetry. An AC voltage of constant amplitude and constant frequency is present at primary winding 36, with the frequency thereof generally ranging from 50 Hz to 500 kHz.

When piston rod 14 is moved relative to stationary magnetic flux sensor 22, 32 along the magnetically scannable measurement strips, the coupling factors between the windings are altered. For example, if primary winding 36 is located directly above a measurement strip 34, then the arrangement is symmetrical, the voltages of secondary windings are canceled out, and no output signal is generated. As soon as piston rod 14 is displaced, an uneven magnetic coupling is present, and as a result, an output voltage is generated at the secondary windings. A directional signal can be generated by a correlation with the excitation voltage. The output signal is sinusoidal and highly stable, and therefore, very high resolution can be achieved.

FIG. 3 shows sensor head arrangement 22, 32, according to the principle of differential transformer 34 represented in FIG. 2, over selectively hardened measurement strip 34. In each case, a measurement strip 34 and an associated blank space 62 together form a sector.

With the method described thus far, however, an absolute value measurement cannot be achieved.

According to the invention, a so-called sector pointer is proposed for absolute displacement measurement. This measurement is implemented using the second magnetically scannable structure 28 arranged on bottom side 26 of piston 14. Said structure comprises two measurement strips 30 extending at an angle along longitudinal axis 16 of piston 14. Measurement strip 30 is represented in various positions in FIG. 4 together with second magnetic flux sensor 32.

The displacement measuring system according to FIG. 4 has lower resolution but a substantially larger measuring range than the displacement measuring system according to FIG. 3. The structure of magnetic flux sensor 32 corresponds to that of magnetic flux sensor 22. However, one sensor surface 66 of magnetic flux sensor 32 is arranged transversely to longitudinal axis 16, so that when piston rod 14 moves in a linear fashion along magnetic flux sensor 32, measurement strip 30 passes transversely over sensor head 66 in the direction of arrow 68, for example, wherein a sinusoidal output signal is generated on the basis of the steady coupling changes.

In combination, the measuring systems represented in FIG. 3 and FIG. 4 form a highly precise, absolute displacement measuring system.

FIG. 5a shows a front view of a sensor ring 68 for holding sensors 22, 32, while FIG. 5b shows sensor ring 68 in a sectional illustration. Magnetic flux sensor 32 comprises the three SMD inductors, which are arranged one in behind the other in the direction of longitudinal axis 16, while magnetic flux sensor 32 extends along an inner edge 70 of sensor ring 68 in the circumferential direction. Sensor ring 68 enables the drive system according to FIG. 1 to be fitted in a simple manner, including post-market, with a displacement measuring system, wherein sensor ring 24 is secured to an end face of cylinder 12, coaxially to piston rod 14.

1. A method for determining a position of a first component (14) in relation to a second component (12), wherein at least one first magnetically scannable structure (34) formed on a surface (18) of the first component (14) is detected by means of at least one first magnetic flux sensor (22) connected to the second component (12) during a relative movement between the first component (14) and the first magnetic flux sensor (22), wherein to execute a differential measurement method, a differential transformer is used as magnetic flux sensor (22), said transformer comprising a primary winding (36) and two secondary windings (40, 42), which are interconnected such that the difference between the signals of the interconnected secondary windings results directly in their respective output signal, wherein the voltages generated by the primary winding in the secondary windings are mutually canceled out when the windings are symmetrically magnetically coupled, wherein the first magnetically scannable structure is embodied as magnetically scannable regions of a metallic surface that have a different permeability or magnetic property, such that the magnetic coupling of the windings changes during the relative movement of the first differential transformer along the magnetically scannable structure, whereby a continuous incremental signal is present at the output of the first differential transformer, the magnitude of which is a measure of asymmetry, and from which the relative position of the first component is determined,
characterized in that
a second magnetically scannable structure (28) arranged on the surface (28) of the first component (14) is detected by means of at least one second differential transformer (32) connected to the second component (14), and in that the absolute position of the first component (14) is determined from the continuous, incremental signal sequence of the first differential transformer (22) and a continuous, steady output signal of the second differential transformer (32).

2. The method according to claim 1,
characterized in that
magnetically scannable measurement strips (20) which extend in the form of increments of a scale, preferably equidistant along the longitudinal axis (16) of the first component (14), transversely to the longitudinal axis (16), are used as the first magnetically scannable structure (34), and in that a continuous sine signal or cosine signal is generated with a relative movement of the measurement strips (22).

3. The method according to claim 1,
characterized in that
two magnetically scannable measurement strips (30) which extend in a V-shape along the longitudinal axis (16), symmetrically to the longitudinal axis (16) of the component (14), are used as the second magnetically scannable structure (28).

4. The method according to claim 3,
characterized in that
during a linear movement of the component (14), the measurement strips (30) are moved transversely to a sensor surface (64) of the second magnetic flux sensor (32) along the sensor surface, so that the continuous, steady output signal that is dependent on the position of the first component (14) is generated in the second magnetic flux sensor (32).

5. The method according to claim 1,
characterized in that
at least two of the first magnetic flux sensors (22) are arranged spatially offset from one another such that, during a linear movement of the component (14), a front first magnetic flux sensor generates a sine signal and a rear first magnetic flux sensor (22) generates a cosine signal.

6. An arrangement for determining a position of a first component (14) in relation to a second component (12), comprising at least one first magnetic flux sensor (22), connected to the second component (12), for detecting a first magnetically scannable structure (20) formed on a surface (18) of the first component (14) during a relative movement between the first component (14) and the first magnetic flux sensor (22), wherein the first magnetic flux sensor (22) is embodied as a differential transformer having a primary winding (36) and two secondary windings (40, 42) which are interconnected such that the difference between the signals of the connected secondary windings results directly in their respective output signal, so that the voltages generated by the primary winding in the secondary windings are mutually canceled out when the windings are symmetrically magnetically coupled, wherein the magnetically scannable structure is formed on the metallic surface of the first component in the form of regions of different permeability or magnetic property, such that the magnetic coupling of the windings changes during a relative movement of the differential transformer along the measurement structure, whereby a continuous signal is present at the output of the first differential transformer, the magnitude of which is a measurement of asymmetry, and the relative position of the first component can be determined from the course of this continuous, incremental signal,
characterized in that
the second component (12) has at least one second magnetic flux sensor (32), embodied as a differential transformer, for determining the absolute position of the first component (14), in that the first component (14) has at least one second magnetically scannable structure (28) extending along a longitudinal axis (16) of the first component (14), which can be scanned by the second differential transformer (32), wherein the second differential transformer (32) generates a continuous, steady output signal during a relative movement along the second magnetically scannable structure (28), wherein the absolute position of the first component can be determined with the help of the steady output signal of the second differential transformer.

7. The arrangement according to claim 6,
characterized in that
the first magnetically scannable structure (20) comprises measurement strips (34) that extend transversely to a longitudinal axis (16) of the first component (14) and are preferably arranged equidistant, one behind the other, along the longitudinal axis (16).

8. The arrangement according to claim 7,
characterized in that
the width B of each of the measurement strips (20) ranges from 0.5 mm to 10 mm, preferably with B=5 mm, and in that the measurement strips (34) are spaced a distance A from one another, which distance is within the range of 1 mm≦A≦20 mm, preferably with A=5 mm.

9. The arrangement according to claim 6,
characterized in that
the second magnetically scannable structure (28) comprises two measurement strips (30) extending in a V-shape relative to one another along the longitudinal axis (16), which strips traverse a sensor surface (84) of the second magnetic flux sensor (32) during a linear movement of the first component (14).

10. The arrangement according to claim 6
characterized in that
primary and secondary windings (36, 40, 42) of the differential transformer (22, 32) are embodied as inductors (36, 40, 42), which are arranged in a single plane and are arranged adjacent to one another on a substrate so as to form a sensor surface (64, 66) such that the magnetic axes thereof extend parallel with one another and/or such that the sensor surface (64, 66) has a total extension E in the direction of movement of the magnetic structure (34) that is within the range of 1.5 mm≦E≦30 mm.

11. The arrangement according to claim 10,
characterized in that
the inductor (36, 40, 42) are embodied as an SMD (surface mounted device) inductor or miniature inductor and/or in that each of the inductors (36, 40, 42) has an extension C in the direction of movement of the magnetic structure (34) that is within the range of 1 mm≦C≦20 mm, and has a length D that is within the range of 1 mm≦D≦20 mm.

12. The arrangement according to claim 6,
characterized in that
the arrangement is a hydraulic, electric or pneumatic drive (10), wherein the first component (14) is embodied as a piston rod and wherein the second component (12) is embodied as a hydraulic, electric or pneumatic cylinder within which the piston rod can be longitudinally displaced.

13. The arrangement according to claim 6,
characterized in that
the magnetic flux sensor (22, 32) is arranged on an inner edge (70) of a sensor holder (24) arranged on the hydraulic or pneumatic cylinder (12), bordering the surface (18) of the piston rod (14) for detecting the measurement strip arrangement (20, 28), wherein the sensor holder (24) is preferably embodied as a sensor ring that is attached to the end face of the cylinder (12).

14. The arrangement according to claim 1,
characterized in that
the first and second magnetically scannable measurement strip arrangements (30, 34) are formed on diametrically opposite surfaces (18, 26) of the piston rod (14) and in that the first and second magnetic flux sensors (22, 32) are arranged in diametrically opposite positions of the sensor holder (24) encompassing the end face and/or in that the first and second magnetic flux sensors (22, 32) are each arranged in a recess in an inner surface (70) of the sensor holder (24).

15. The arrangement according to claim 1,
characterized in that
a plurality of first or second magnetic flux sensors (22, 32) is provided, which are offset from one another spatially such that during a linear movement of the first component, a sine signal and a cosine signal are generated as output signals.
